(19) United States
(12) Patent Application Publication
(10) Pub. No.: US 2020/0127235 A1
(43) Pub. Date: Apr. 23, 2020

(54) FLEXIBLE OLED DEVICE AND METHOD FOR MANUFACTURING SAME

(71) Applicant: Wuhan China Star optoelectronics Semiconductor Display Technology Co., Ltd., Wuhan (CN)

(72) Inventor: Jun CAO, Wuhan (CN)

(21) Appl. No.: 16/319,834

(22) PCT Filed: Aug. 16, 2018
(86) PCT No.: PCT/CN2018/100725

§ 371 Date: Jan. 23, 2019

(30) Foreign Application Priority Data
Jun. 12, 2018 (CN) 201810602410.1

(51) Int. Cl. H01L 51/52; H01L 51/00; H01L 27/32; H01L 51/56

(52) U.S. Cl. CPC H01L 51/5259; H01L 51/0097; H01L 27/3246; H01L 27/3258; H01L 2251/5369; H01L 51/56; H01L 51/0005; H01L 2251/30; H01L 2251/5338; H01L 51/5256

(57) ABSTRACT

The present disclosure provides a flexible organic light-emitting diode (OLED) device and a method for manufacturing same. The flexible OLED device includes a pixel defining layer disposed on the planarization layer within a portion of a display area and on the planarization layer within a non-display area, a first inorganic layer disposed on the pixel defining layer, a first barrier layer disposed on the first inorganic layer within the non-display area, a first organic layer disposed on the first inorganic layer within the display area, and a second inorganic layer disposed on the first barrier layer and the first organic layer.

### FIELD OF INVENTION

The present disclosure relates to the field of display technology, and more particularly to a flexible OLED device and a method for manufacturing the same.

### BACKGROUND

In the field of flat panel displays, TFT-LCDs have a majority of display market owing to its mature technique, and because they could be stably mass produced. Compared to LCDs, organic light-emitting diode (OLED) devices possess outstanding properties, including being self-illuminating, having low power consumption, and being flexible, and thus are considered as new generation display technique that could be used in various products.

Nevertheless, OLED devices are sensitive to water and oxygen. In particular, metal electrodes and organic light-emitting materials disposed in OLED devices are likely to age more quickly if being contacted by water or oxygen. In order to prevent them from being damaged and protect the same, metal electrodes and organic light-emitting materials are required to be encapsulated. Considering flexibility of OLED devices, thin film encapsulation is now one way widely used to arrive at such objective. To achieve thin film encapsulation, a stacked structure of inorganic/organic film is formed, where inorganic film is configured to block water and oxygen, while organic film is configured to release stress generated during bending process of display and to cover particulates.

However, organic film in the stacked encapsulation structure is so flowable that it is liable to flow outward to outer boundary of display area. If organic film flows to exceed beyond the region where inorganic film is formed, water and oxygen would easily enter into OLED devices in lateral direction, thus damaging OLED devices.

Therefore, there is a need to provide a flexible OLED device and a method for manufacturing the same to solve problems encountered in the prior art.

### SUMMARY OF DISCLOSURE

The present disclosure provides a flexible organic light-emitting diode (OLED) device and a method for manufacturing the same, which increases stability and lifetime of OLED devices.

To solve the aforementioned problems, the present disclosure provides a flexible organic light-emitting diode (OLED) device, comprising:
a planarization layer disposed on a flexible substrate;
a pixel defining layer disposed on the planarization layer within a portion of a display area and on the planarization layer within a non-display area, wherein the flexible OLED device includes the display area and the non-display area;
a first inorganic layer disposed on the pixel defining layer, wherein the first inorganic layer covers the display area and the non-display area;
a first barrier layer disposed on the first inorganic layer within the non-display area, wherein the first barrier layer includes a desiccant;
a first organic layer disposed on the first inorganic layer within the display area; and
a second inorganic layer disposed on the first barrier layer and the first organic layer.

In the flexible OLED device of the present disclosure, the OLED device of the present disclosure further comprises:
a second barrier layer disposed on the second inorganic layer within the non-display area;
a second organic layer disposed on the second inorganic layer within the display area; and
a third inorganic layer disposed on the second barrier layer and the second organic layer.

In the flexible OLED device of the present disclosure, the second barrier layer includes the desiccant.

In the flexible OLED device of the present disclosure, the second inorganic layer covers the display area and the non-display area.

In the flexible OLED device of the present disclosure, the first barrier layer is made of a material selected from a group consisting of acrylate, epoxy resin, polyimide, organic silicon compound, and any combinations thereof.

In the flexible OLED device of the present disclosure, the first organic layer covers the display area only, and an outer boundary of the first organic layer does not exceed beyond the first barrier layer.

In the flexible OLED device of the present disclosure, the first inorganic layer is made of a material selected from a group consisting of SiNₓ, SiOₓN_{y}, SiOₓ, SiCₓN_{y}, ZnO, AlOₓ, and any combinations thereof.

In the flexible OLED device of the present disclosure, the first organic layer is made of a material selected from a group consisting of acrylate, HMDSO, polyacrylate, polycarbonate, polystyrene, and any combinations thereof.

In the flexible OLED device of the present disclosure, the desiccant includes at least one of CaO, BaO, and SrO in nanoparticle form.

In addition, the present disclosure provides a flexible organic light-emitting diode (OLED) device, comprising:
a planarization layer disposed on a flexible substrate;
a pixel defining layer disposed on the planarization layer within a portion of a display area and on the planarization layer within a non-display area, wherein the flexible OLED device includes the display area and the non-display area;
a first inorganic layer disposed on the pixel defining layer;
a first barrier layer disposed on the first inorganic layer within the non-display area;
a first organic layer disposed on the first inorganic layer within the display area; and
a second inorganic layer disposed on the first barrier layer and the first organic layer.

In the flexible OLED device of the present disclosure, the OLED device further comprises:
a second barrier layer disposed on the second inorganic layer within the non-display area;
a second organic layer disposed on the second inorganic layer within the display area; and
a third inorganic layer disposed on the second barrier layer and the second organic layer.

In the flexible OLED device of the present disclosure, the second barrier layer includes a desiccant.

In the flexible OLED device of the present disclosure, the first barrier layer includes a desiccant.

In the flexible OLED device of the present disclosure, the first barrier layer is made of a material selected from a group consisting of acrylate, epoxy resin, polyimide, organic silicon compound, and any combinations thereof.

In the flexible OLED device of the present disclosure, the desiccant includes at least one of CaO, BaO, and SrO in nanoparticle form.

Moreover, the present disclosure provides a method for manufacturing a flexible organic light-emitting diode (OLED) device, comprising steps of:
forming a planarization layer on a flexible substrate, wherein the flexible OLED device includes a display area and a non-display area;
forming a pixel defining layer on the planarization layer within a portion of the display area and on the planarization layer within the non-display area;
forming a first inorganic layer on the pixel defining layer;
forming a first barrier layer on the first inorganic layer within the non-display area;
forming a first organic layer on the first inorganic layer within the display area; and
forming a second inorganic layer on the first barrier layer and the first organic layer.

In the method for manufacturing the flexible OLED device according to the present disclosure, the method further comprises:
forming a second barrier layer on the second inorganic layer within the non-display area;
forming a second organic layer on the second organic layer within the display area; and
forming a third inorganic layer on the second barrier layer and the second organic layer.

In the method for manufacturing the flexible OLED device according to the present disclosure, the first barrier layer includes a desiccant.

In the method for manufacturing the flexible OLED device according to the present disclosure, the first barrier layer is made of a material selected from a group consisting of acrylate, epoxy resin, polyimide, organic silicon compound, and any combinations thereof.

In the method for manufacturing the flexible OLED device according to the present disclosure, the step of forming the first barrier layer on the first inorganic layer within the non-display area includes:
forming the first barrier layer on the first inorganic layer within the non-display area by an inkjet printing (IJP) technique or a dispensing technique.

The present disclosure provides a flexible OLED device and a method for manufacturing the same. By improving the conventional encapsulation structure and method for forming same, the organic layer outward-flowing problem is efficiently avoided, and pathway of water and oxygen reaching the organic light-emitting materials is made much farther, increasing stability and lifetime of OLED devices.

### BRIEF DESCRIPTION OF DRAWINGS

FIG. 1 is a schematic diagram showing a structure of a flexible organic light-emitting diode (OLED) device according to one embodiment of the present disclosure.

FIG. 2 shows a top view of a flexible organic light-emitting diode (OLED) device according to one embodiment of the present disclosure.

FIG. 3 is a schematic diagram showing a structure of a flexible organic light-emitting diode (OLED) device according to another embodiment of the present disclosure.

### DETAILED DESCRIPTION

The following embodiments refer to the accompanying drawings for exemplifying specific implementable embodiments of the present disclosure. Moreover, directional terms described by the present disclosure, such as upper, lower, front, back, left, right, inner, outer, side, etc., are only directions by referring to the accompanying drawings, and thus the used directional terms are used to describe and understand the present disclosure, but the present disclosure is not limited thereto. In the drawings, the same reference symbol represents the same or similar components.

Please refer to FIG. 1, which is a schematic diagram showing a structure of a flexible organic light-emitting diode (OLED) device according to one embodiment of the present disclosure.

As shown in FIG. 1, the flexible OLED device includes a display area 101 and a non-display area 102. The flexible OLED device includes a flexible substrate 100, a planarization layer 210, a pixel defining layer 220 and an OLED display layer 230, a first inorganic layer 310, a first barrier layer 410, a first organic layer 320, and a second inorganic layer d 330.

The flexible substrate 100 includes a glass or polyimide (PI) substrate and a driving circuit. The planarization layer 210 is disposed on the flexible substrate 100. The pixel defining layer 220 is disposed on the planarization layer 210 within a portion of the display area 101 and on the planarization layer 210 within the non-display area 102. The OLED display layer 230 is disposed on the planarization layer 210 within other portion of the display area 101. The OLED display layer 230 includes a plurality of organic light-emitting elements. The OLED display layer 230 includes an anode, a hole injection/transmission layer, a light-emitting layer, an electron transmission/injection layer, and a cathode in the cross-sectional view. The pixel defining layer 220 within the display area 101 is disposed between organic light-emitting elements of the OLED display layer 230.

The first inorganic layer 310 is disposed on the pixel defining layer 220. Specifically, the first inorganic layer 310 is disposed on the pixel defining layer 220 and the OLED display layer 230. The first inorganic layer 310 covers the display area 101 and the non-display area 102. The first barrier layer 410 is disposed on the first inorganic layer 310 within the non-display area 102.

Preferably, the first barrier layer 410 is made of a material selected from a group consisting of acrylate, epoxy resin, polyimide, organic silicon compound, and any combinations thereof.

The first organic layer 320 is disposed on the first inorganic layer 310 within the display area 101. The first organic layer 320 is made of a material selected from a group consisting of acrylate, HMDSO, polyacrylate, polycarbonate, and polystyrene, and any combinations thereof. The first organic layer 320 covers the display area 101 only, and an outer boundary of the first organic layer 320 does not exceed beyond the first barrier layer 410. The second inorganic layer 330 is made of a material selected from a group consisting of SiNₓ, SiOₓN_{y}, SiOₓ, SiCₓN_{y}, ZnO, AlOₓ, and any combinations thereof. The second inorganic layer 330 is disposed on the first barrier layer 410 and the first organic layer 320. The second inorganic layer 330 covers the display area and the non-display area.

In addition, the present disclosure provides a method for manufacturing a flexible organic light-emitting diode (OLED) device including the following steps.

In a step S101, a planarization layer is formed on a flexible substrate.

The flexible OLED device includes a display area 101 and a non-display area 102. The planarization layer covers the display area and the non-display area. The planarization layer can be formed within the display area and the non-display area using a same mask process that includes exposure and developing treatment.

In a step S102, a pixel defining layer is formed on the planarization layer within a portion of the display area and on the planarization layer within the non-display area.

Specifically, a pixel defining layer 220 is formed first on the planarization layer 210 within the display area 101 and on the planarization layer 210 within the non-display area 102. The pixel defining layer 220 formed within the display area 101 includes a plurality of pixel defining units. Then, an OLED display layer 230 is formed between the pixel defining units within the display area 101. The OLED display layer 230 includes a plurality of organic light-emitting elements.

In a step S103, a first inorganic layer is formed on the pixel defining layer.

Specifically, a first inorganic layer 310 is deposited on the pixel defining layer 220 and the OLED display layer 230 by atomic layer deposition (ALD), pulsed laser deposition (PLD), sputtering, plasma-enhanced chemical vapor deposition (PECVD) techniques, etc. The first inorganic layer 310 is made of a material selected from a group consisting of SiNₓ, SiOₓN_{y}, SiOₓ, SiCₓN_{y}, ZnO, AlOₓ, and any combinations thereof. The first inorganic layer 310 covers the display area 101 and the non-display area 102.

In a step S104, a first barrier layer is formed on the first inorganic layer within the non-display area.

Specifically, a first barrier layer 410 is formed on the planarization layer 210, the pixel defining layer 220, and the first inorganic layer 310 within the non-display area 102. The first barrier layer 410 can be formed using an inkjet printing (IJP) technique or a dispensing technique. The first barrier layer 410 is made of a material selected from a group consisting of acrylate, epoxy resin, polyimide, organic silicon compound, and any combinations thereof.

Preferably, the first barrier layer includes a desiccant. The desiccant includes at least one of CaO, BaO, SrO, and any combinations thereof in nanoparticle form, or could be a liquid type desiccant (AqvaDry series).

In a step S105, a first organic layer is formed on the first inorganic layer within the display area.

Specifically, a first organic layer 320 of the stacked encapsulation structure is formed on the first inorganic layer 310 within the display area 101 by an inkjet printing (IJP) technique, PECVD, or a slot coating technique. The first organic layer 320 is made of a material selected from a group consisting of acrylate, HMDSO, polyacrylate, polycarbonate, polystyrene, and any combinations thereof. The first organic layer 320 covers the display area 101 only, and an outer boundary of the first organic layer 320 does not exceed beyond the first barrier layer 410.

In a step S106, a second inorganic layer is formed on the first barrier layer and the first organic layer.

Specifically, a second inorganic layer 330 is deposited on the first barrier layer 410 and the first organic layer 320 by atomic layer deposition (ALD), pulsed laser deposition (PLD), sputtering, plasma-enhanced chemical vapor deposition (PECVD) techniques, etc. The second inorganic layer 330 is made of a material selected from a group consisting of SiNₓ, SiOₓN_{y}, SiOₓ, SiCₓN_{y}, ZnO, AlOₓ, and any combinations thereof. The second inorganic layer 330 covers the display area 101 and the non-display area 102. For example, the second inorganic layer 330 covers the first barrier layer 410, the pixel defining layer 220, and the planarization layer 210 within the display area 101.

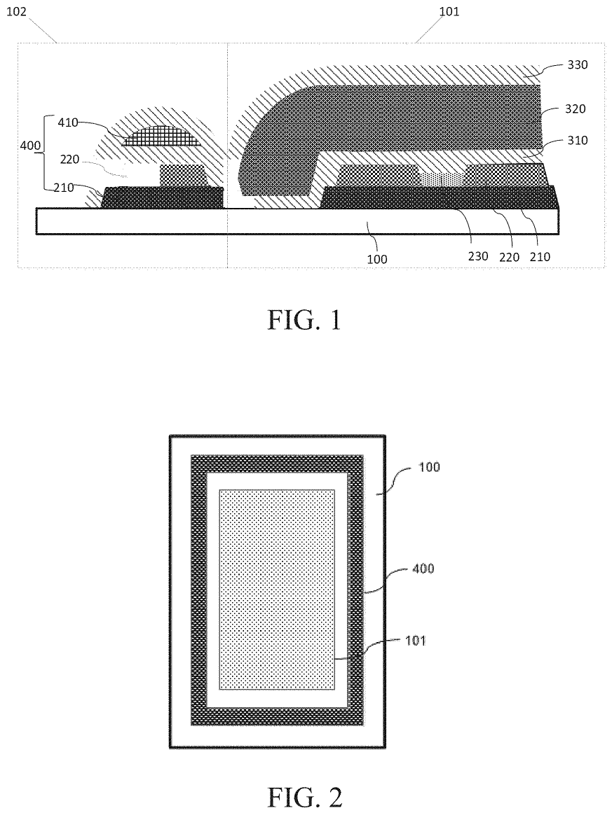

Therefore, as shown in FIG. 2, the method of this embodiment is characterized in forming a blocking body 400 around a periphery of the display area 101 of the OLED device to prevent the organic layer of the stacked encapsulation structure from flowing outward. The blocking body 400 has a laminated structure, which includes the planarization layer 210, the pixel defining layer 220, the first inorganic layer 310, the first barrier layer 410, and the second inorganic layer 330 within the non-display area. The two bottommost layers of the blocking body 400 are formed using a same mask process as that used for forming the planarization layer 210 and the pixel defining layer 220 within the display area, respectively. The upper first barrier layer 410 of the blocking body 400 is formed by an inkjet printing (IJP) technique or a dispensing technique after the first inorganic layer of the stacked encapsulation structure is formed and before the first organic layer of the stacked encapsulation structure is formed. Such a structure of the blocking body 400 not only ensures that a barrier layer is sandwiched between two adjacent inorganic layers to efficiently prevent the organic layer from flowing outward and to prevent extension of the inorganic layer, but makes pathway of water and oxygen reaching the organic light-emitting materials much farther, thus increasing stability and lifetime of OLED devices. It is understood that the first organic layer 320 cover the display area, but the outer boundary of the first organic layer 320 does not exceed beyond the blocking body 400.

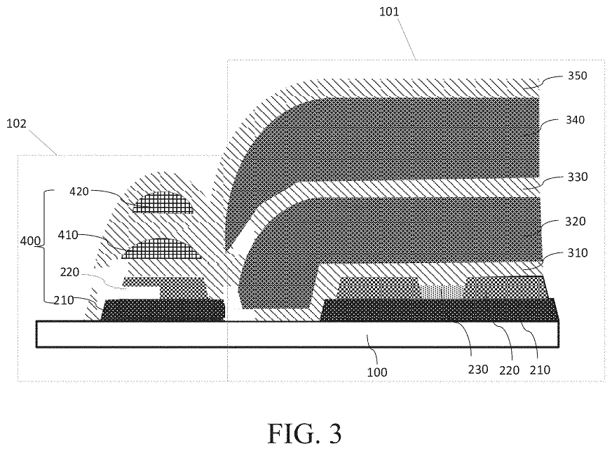

Please refer to FIG. 3, which is a schematic diagram showing a structure of a flexible organic light-emitting diode (OLED) device according to another embodiment of the present disclosure.

As shown in FIG. 3, the flexible OLED device of this embodiment differs from the flexible OLED device of the above embodiment in that the flexible OLED device of this embodiment further includes a second barrier layer 420, a second organic layer 340, and a third inorganic layer 350.

The second barrier layer 420 is disposed on the second inorganic layer 330 within the non-display area. The second organic layer 340 is disposed on the second inorganic layer 330 within the display area. The third inorganic layer 350 is disposed on the second barrier layer 420 and the second organic layer 340.

Furthermore, the present disclosure provides a method for manufacturing a flexible OLED device. The method of this embodiment differs from the method of the above embodiment in that the method of this embodiment further includes the following steps.

In a step S107, a second barrier layer is formed on the second inorganic layer within the non-display area.

Specifically, a second barrier layer 420 (i.e., the fourth layer) is formed directly on the first to third layers of the blocking body and on the second inorganic layer 330 within the non-display area by an inkjet printing (IJP) technique or a dispensing technique. The second barrier layer 420 is made of a material selected from a group consisting of acrylate, epoxy resin, polyimide, organic silicon compound, and any combinations thereof.

Preferably, the second barrier layer 420 includes a desiccant. The desiccant includes at least one of CaO, BaO, SrO, and any combinations thereof in nanoparticle form, or could be a liquid type desiccant (AqvaDry series). It is understood that only one of the second barrier layer 420 and the first barrier layer 410 includes a desiccant.

In a step S108, a second organic layer is formed on the second organic layer within the display area.

Specifically, a second organic layer 340 of the stacked encapsulation structure is formed on the second inorganic layer 330 within the display area 101 by an inkjet printing (IJP) technique, PECVD, or a slot coating technique. The second organic layer 340 is made of a material selected from a group consisting of acrylate, HMDSO, polyacrylate, polycarbonate, polystyrene, and any combinations thereof. The second organic layer 340 covers the display area 101 only, and an outer boundary of the second organic layer 340 does not exceed beyond the second barrier layer 420. That is, the second organic layer 340 covers the display area 101, and the outer boundary of the second organic layer 340 does not exceed beyond the blocking body 400.

In a step S109, a third inorganic layer is formed on the second barrier layer and the second organic layer.

Specifically, a third inorganic layer 350 is deposited on the second organic layer 340 and the second barrier layer 420 by atomic layer deposition (ALD), pulsed laser deposition (PLD), sputtering, plasma-enhanced chemical vapor deposition (PECVD) techniques, etc. The third inorganic layer 350 is made of a material selected from a group consisting of SiNₓ, SiOₓN_{y}, SiOₓ, SiCₓN_{y}, ZnO, AlOₓ, and any combinations thereof. The third inorganic layer 350 covers the display area 101 and the non-display area 102. The third inorganic layer 350 covers the first to fourth layers of the blocking body 400.

Therefore, as shown in FIG. 2, the method of this embodiment is characterized in forming a blocking body 400 around a periphery of the display area 101 of the OLED device to prevent the organic layer of the stacked encapsulation structure from flowing outward. The blocking body 400 has a laminated structure, which includes the planarization layer 210, the pixel defining layer 220, the first inorganic layer 310, the first barrier layer 410, the second inorganic layer 330, the second barrier layer 420, and the third inorganic layer 350 within the non-display area. The second barrier layer 420 of the blocking body 400 is formed by an inkjet printing (IJP) technique or a dispensing technique after the second inorganic layer of the stacked encapsulation structure is formed and before the second organic layer of the stacked encapsulation structure is formed. Such a structure of the blocking body 400 not only ensures that a barrier layer is sandwiched between two adjacent inorganic layers to efficiently prevent the organic layer from flowing outward and to prevent extension of the inorganic layer, but makes pathway of water and oxygen reaching the organic light-emitting materials much farther, thus increasing stability and lifetime of OLED devices.

The present disclosure provides a flexible OLED device and a method for manufacturing the same. By improving the conventional encapsulation structure and method for forming same, the organic layer outward-flowing problem is efficiently avoided, and pathway of water and oxygen reaching the organic light-emitting materials is made much farther, increasing stability and lifetime of OLED devices.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. A flexible organic light-emitting diode (OLED) device, comprising:
a planarization layer disposed on a flexible substrate;
a pixel defining layer disposed on the planarization layer within a portion of a display area and on the planarization layer within a non-display area, wherein the flexible OLED device includes the display area and the non-display area;
a first inorganic layer disposed on the pixel defining layer, wherein the first inorganic layer covers the display area and the non-display area;
a first barrier layer disposed on the first inorganic layer within the non-display area, wherein the first barrier layer includes a desiccant;
a first organic layer disposed on the first inorganic layer within the display area; and
a second inorganic layer disposed on the first barrier layer and the first organic layer.

2. The flexible OLED device according to claim 1, further comprising:
a second barrier layer disposed on the second inorganic layer within the non-display area;
a second organic layer disposed on the second inorganic layer within the display area; and
a third inorganic layer disposed on the second barrier layer and the second organic layer.

3. The flexible OLED device according to claim 2, wherein the second barrier layer includes the desiccant.

4. The flexible OLED device according to claim 2, wherein the second inorganic layer covers the display area and the non-display area.

5. The flexible OLED device according to claim 1, wherein the first barrier layer is made of a material selected from a group consisting of acrylate, epoxy resin, polyimide, organic silicon compound, and any combinations thereof.

6. The flexible OLED device according to claim 1, wherein the first organic layer covers the display area only, and an outer boundary of the first organic layer does not exceed beyond the first barrier layer.

7. The flexible OLED device according to claim 1, wherein the first inorganic layer is made of a material selected from a group consisting of SiNₓ, SiOₓN_{y}, SiOₓ, SiCₓN_{y}, ZnO, AlOₓ, and any combinations thereof.

8. The flexible OLED device according to claim 1, wherein the first organic layer is made of a material selected from a group consisting of acrylate, HMDSO, polyacrylate, polycarbonate, polystyrene, and any combinations thereof.

9. The flexible OLED device according to claim 1, wherein the desiccant includes at least one of CaO, BaO, and SrO in nanoparticle form.

10. A flexible organic light-emitting diode (OLED) device, comprising:
a planarization layer disposed on a flexible substrate;
a pixel defining layer disposed on the planarization layer within a portion of a display area and on the planarization layer within a non-display area, wherein the flexible OLED device includes the display area and the non-display area;
a first inorganic layer disposed on the pixel defining layer;
a first barrier layer disposed on the first inorganic layer within the non-display area;
a first organic layer disposed on the first inorganic layer within the display area; and
a second inorganic layer disposed on the first barrier layer and the first organic layer.

11. The flexible OLED device according to claim 10, further comprising:
a second barrier layer disposed on the second inorganic layer within the non-display area;
a second organic layer disposed on the second inorganic layer within the display area; and
a third inorganic layer disposed on the second barrier layer and the second organic layer.

12. The flexible OLED device according to claim 11, wherein the second barrier layer includes a desiccant.

13. The flexible OLED device according to claim 10, wherein the first barrier layer includes a desiccant.

14. The flexible OLED device according to claim 10, wherein the first barrier layer is made of a material selected from a group consisting of acrylate, epoxy resin, polyimide, organic silicon compound, and any combinations thereof.

15. The flexible OLED device according to claim 10, wherein the desiccant includes at least one of CaO, BaO, and SrO in nanoparticle form.

16. A method for manufacturing a flexible organic light-emitting diode (OLED) device, comprising steps of:
forming a planarization layer on a flexible substrate, wherein the flexible OLED device includes a display area and a non-display area;
forming a pixel defining layer on the planarization layer within a portion of the display area and on the planarization layer within the non-display area;
forming a first inorganic layer on the pixel defining layer;
forming a first barrier layer on the first inorganic layer within the non-display area;
forming a first organic layer on the first inorganic layer within the display area; and
forming a second inorganic layer on the first barrier layer and the first organic layer.

17. The method for manufacturing the flexible OLED device according to claim 16, further comprising:
forming a second barrier layer on the second inorganic layer within the non-display area;
forming a second organic layer on the second organic layer within the display area; and
forming a third inorganic layer on the second barrier layer and the second organic layer.

18. The method for manufacturing the flexible OLED device according to claim 16, wherein the first barrier layer includes a desiccant.

19. The method for manufacturing the flexible OLED device according to claim 16, wherein the first barrier layer is made of a material selected from a group consisting of acrylate, epoxy resin, polyimide, organic silicon compound, and any combinations thereof.

20. The method for manufacturing the flexible OLED device according to claim 16, wherein the step of forming the first barrier layer on the first inorganic layer within the non-display area includes:
forming the first barrier layer on the first inorganic layer within the non-display area by an inkjet printing (IJP) technique or a dispensing technique.
